(19) United States
(12) Patent Application Publication
(10) Pub. No.: US 2016/0161991 A1
(43) Pub. Date: Jun. 9, 2016

(54) Ultra-Thin, Passively Cooled Sapphire Windows

(71) Applicant: Rubicon Technology, Inc., Bensenville, IL (US)

(72) Inventors: John P. Ciraldo, Elgin, IL (US); Eric G. Allain, Naperville, IL (US)

(21) Appl. No.: 14/949,073

(22) Filed: Nov. 23, 2015

Related U.S. Application Data
(60) Provisional application No. 62/088,858, filed on Dec. 8, 2014.

(51) Int. Cl. G06F 1/16; C30B 29/04

(52) U.S. Cl. CPC G06F 1/1633; C30B 29/04

(57) ABSTRACT

A system and process coat or create a composite material with a layer of diamond film deposited on a sapphire substrate. The diamond film may be applied using, e.g., a microwave field and a hydrocarbon gas environment. The diamond film creates a stronger and more scratch-resistant substrate that is less prone to breaking or cracking while also providing improved heat dissipation properties. The sapphire substrate with diamond film may be a window for use in devices such as, e.g., consumer devices, mobile phones, tablet computers, optical devices, watches, and the like.

### CROSS-REFERENCE TO RELATED APPLICATIONS

This application claims benefit and priority to U.S. Provisional Application No. 62/088,858 filed Dec. 8, 2014, the disclosure of which is incorporated by reference herein in its entirety.

### BACKGROUND

1.0 Field of the Disclosure

The present disclosure relates to a system and a method for, among other things, coating a sapphire material (such as, e.g., a substrate) with a diamond coating or film to create a cost-effective hard, scratch-resistant coating that has enhanced thermal cooling properties.

2.0 Related Art

Hard, scratch-resistant windows are important for cell phones and other devices that are subject to harsh conditions during use. Different types of materials have been used for such windows including, e.g., enhanced glass. However, cracking and scratching of these windows, along with thermal dissipation problems, are still an issue for many different devices. For example, as the density of the electronics in electronic devices increases, so do the thermal dissipation challenges to effectively maintain a suitable operational temperature for the device. While sapphire windows are typically a satisfactory solution for the cracking and scratching problem, their use does not adequately address the thermal dissipation issue.

### SUMMARY OF ILLUSTRATIVE EMBODIMENTS

According to one non-limiting example of the disclosure, a system, a method, and a device are provided to, among other things, coat a substrate material (such as, e.g., a sapphire substrate) to create a cost-effective, hard, scratch-resistant diamond-based coating with thermal dissipation characteristics.

In one embodiment, a window for use in a device may comprise a sapphire material and a diamond film layer configured upon the sapphire material. The device may comprise one of: a mobile phone, a tablet computer, a watch crystal, a laptop computer and a consumer device. The diamond film layer may comprise a single-crystal or poly-crystalline diamond. The diamond film layer may comprise a nano-crystalline diamond. The sapphire material may be configured having a thickness of about 100 μm to about 500 μm. The sapphire material may be configured having a thickness greater than 500 μm. The sapphire material may be configured having a thickness less than 100 μm. The diamond film layer may have a thickness selected from a range of about 1 nm to about 10 μm. The diamond film layer may have a thickness selected from the range of about 2 nm to about 100 nm. The resulting window may have a thermal conductivity greater than 26 W m⁻¹ K⁻¹ at 300K through the face (out-of-plane) of the resulting window. The in-plane thermal conductivity may be greater than 1000 W m⁻¹ K⁻¹ at 300K along the surface 453 of the resulting window.

In one embodiment, a device may comprise a sapphire window and a diamond layer coating, the sapphire window and diamond layer providing enhanced thermal dissipation properties to dissipate heat generated by the device. The device may comprise one of: a mobile phone, a tablet computer, a watch crystal, a laptop computer a consumer device, and the like. The diamond layer may comprise a single or poly-crystalline diamond. The diamond layer may comprise a nano-crystalline diamond. The sapphire window may be configured with a thickness of about 100 μm to about 500 μm. The sapphire window may be configured with a thickness greater than 500 μm. The sapphire window may be configured with a thickness less than 100 μm. The diamond layer may have a thickness selected from a range of about 1 nm to about 10 μm. The diamond film layer may have a thickness selected from the range of about 2 nm to about 100 nm. The diamond layer may have a thickness of about 100 nm to about 5 mm. The diamond layer may comprise a film. The resulting window (the sapphire window and diamond layer) may have a thermal conductivity greater than 26 W m−1 K−1 at 300K through the face (out-of-plane) of the resulting window. However, the in-plane thermal conductivity may be greater than 1000 W m−1 K−1 at 300K along the surface 453 of the resulting window.

In one embodiment, a window for use in a device may comprise a sapphire substrate, a diamond coating configured on the sapphire substrate, the window having a thermal conductivity greater than 26 W m−1 K−1 at 300K through a face of the window and an in-plane thermal conductivity greater than 1000 W m−1 K−1 at 300K along a surface of the window.

In one embodiment, a sapphire substrate is exposed to microwave radiation in a chamber of hydrogen and one or more hydrocarbon gases to form a carbon film on the sapphire substrate. The chamber may be evacuated to a partial pressure. The carbon may be a diamond allotrope.

In one embodiment, a sapphire substrate may be created having an applied carbon film. The carbon (or diamond) film may be bonded to the substrate as a result of Van Der Waals interactions. The sapphire substrate may be transparent. The applied carbon film may be a diamond film. The applied carbon film may comprise a diamond film that creates a matrix with the sapphire substrate and may be formed with or at the surface of the sapphire substrate. The matrix, comprising the substrate and the carbon film on one or more surfaces of the sapphire substrate, may be substantially transparent.

In one embodiment, a system for forming a film on a sapphire substrate is provided, including a source of gas that provides at least a carbon-based gas, a holding device to hold a target sapphire substrate, an environment configured to contain the gas about the target sapphire substrate, and a microwave source configured to project a microwave field towards the target sapphire substrate to create a diamond film upon the target sapphire substrate for creating a stronger and more scratch-resistant substrate with improved thermal dissipation properties. The gas may be or include a hydrogen-based gas. The gas may be or include a hydrocarbon gas. The gas may be methane. The gas may include an inert gas. The gas may include at least one of oxygen and nitrogen. The carbon film may be diamond film. The environment may comprise a chamber configured to create a partial pressure of gas and the microwave source is configured to excite the gas to create plasma within the chamber to deposit the carbon film on the target substrate. The thickness of the created carbon film may be about 1 nm to about 10 μm; but may be more or less. The target sapphire substrate with carbon film may comprise a window usable in at least one of: a mobile phone, a tablet computer, a watch crystal, a laptop computer, and a consumer device. The system may further comprise a computer controller that is configured to control at least one of: targeting of the microwave source, positioning of the holding device relative to the microwave source, flow of the gas, temperature of the holding device, start and stop times of the microwave field, intensity of the microwave field, orientation of the substrate, pressure of the environment, and a thickness of the carbon film.

In one embodiment, a process to create a carbon film on a sapphire material is provided that includes the steps of providing a gas that includes a hydrocarbon gas, and directing a microwave field towards a sapphire substrate, wherein the sapphire substrate is in contact with the hydrocarbon gas, the microwave field creating plasma to produce a layer of carbon film on the sapphire substrate thereby producing a stronger and more scratch resistant substrate with improved thermal dissipation characteristics. The film may be a diamond film. The providing step may provide an environment of the gas, wherein the substrate is in the gas environment. The process may further include the step of providing a holding device to hold the sapphire substrate, wherein the holding device is temperature controlled and adjustable in orientation. The process may further comprise providing a computer controller that is configured to control at least one of: targeting of the microwave source, positioning of the holding device relative to the microwave source, flow of the gas, temperature of the holding device, start and stop times of the microwave field, intensity of the microwave field, orientation of the sapphire substrate, pressure of the environment, and a thickness of the carbon film. The directing step may create a carbon film having a thickness of about 1 nm to about 10 μm. The directing step may create a window usable in, e.g., at least one of: a mobile phone, a tablet computer, a watch crystal, a laptop computer, and a consumer device. The window may be used in other devices as well.

In one embodiment, a process to create a carbon on a sapphire substrate is provided, the process comprising the steps of creating a carbon film on a source substrate and transferring the carbon film to a destination sapphire substrate hereby producing a stronger and more scratch-resistant substrate with improved thermal dissipation characteristics.

In another embodiment, a window for use in a device having at least one heat generating component includes a sapphire material, and a carbon-based transparent heat sink in contact with the sapphire material. The carbon-based transparent heat sink is configured to be in thermally conductive contact with the at least one heat generating component.

The heat sink may include diamond on the sapphire material, which may include a chemically vapor deposited film on the sapphire material. Moreover, in some embodiments, the sapphire material and transparent heat sink may form a combined heat sink.

Additional features, advantages, and embodiments of the disclosure may be set forth or apparent from consideration of the detailed description, drawings and attachment. Moreover, it is to be understood that the foregoing summary of the disclosure and the following detailed description, drawings and attachment are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate embodiments of the disclosure and, together with the detailed description, serve to explain illustrative embodiments of the disclosure. No attempt is made to show structural details of the disclosure in more detail than may be necessary for a fundamental understanding of the disclosure and the various ways in which it may be practiced. In the drawings:

FIG. 1 shows an example of a system for coating a material (such as, e.g., a substrate) utilizing a gas environment and a microwave source, according to illustrative embodiments of the disclosure;

FIG. 2 shows an example of a system for coating a material (such as, e.g., a substrate) utilizing a gas environment and a microwave source, according to illustrative embodiments of the disclosure;

FIG. 3 is a flow diagram of an example process, the steps of the process performed according to illustrative embodiments of the disclosure;

FIGS. 4A-4C together show an example of a simplified process of transfer bonding, according to illustrative embodiments of the disclosure; and

FIG. 5A is an example of a device utilizing a sapphire window configured according to illustrative embodiments of the disclosure.

FIG. 5B is an example of a device utilizing a pre-treated sapphire window, configured in accordance with illustrative embodiments of the invention.

Various embodiments of the present disclosure are further described in the detailed description that follows.

### DETAILED DESCRIPTION OF ILLUSTRATIVE EMBODIMENTS

The disclosure and the various features and advantageous details thereof are explained more fully with reference to the non-limiting embodiments and examples that are described and/or illustrated in the accompanying drawings and detailed in the following description. It should be noted that the features illustrated in the drawing are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments of the disclosure. The examples used herein are intended merely to facilitate an understanding of ways in which the disclosure may be practiced and to further enable those of skill in the art to practice the embodiments of the disclosure. Accordingly, the examples and embodiments herein should not be construed as limiting the scope of the disclosure. Moreover, it is noted that like reference numerals represent similar parts throughout the several views of the drawings.

The terms “including”, “comprising” and variations thereof, as used in this disclosure, mean “including, but not limited to”, unless expressly specified otherwise.

The terms “a”, “an”, and “the”, as used in this disclosure, means “one or more”, unless expressly specified otherwise. The term “about” means within +/−10% unless context indicates otherwise.

Devices that are in communication with each other need not be in continuous communication with each other, unless expressly specified otherwise. In addition, devices that are in communication with each other may communicate directly or indirectly through one or more intermediaries.

Although process steps, method steps, algorithms, or the like, may be described in a sequential order, such processes, methods and algorithms may be configured to work in alternate orders. In other words, any sequence or order of steps that may be described does not necessarily indicate a requirement that the steps be performed in that order. The steps of the processes, methods or algorithms described herein may be performed in any order practical. Further, some steps may be performed simultaneously.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

Currently, there are not any known products or patents known to the inventors related to diamond windows or diamond films on sapphire for mobile electronic devices (or other devices) for protection thereof and for providing a heat sink capability for a device such as an electronic device. An electronic device usually must dissipate heat typically associated with the circuitry of the electronic device. Therefore, dissipating heat more efficiently may improve operational capacity and may improve reliability of the electronic device. Diamond generally has very effective thermal conducting properties.

A diamond coated sapphire window or substrate constructed according to illustrative embodiments described herein may be configured to provide improved thermal conductivity or improved heat dissipation properties for a wide variety of devices. This may permit devices including electronic devices utilizing a diamond coated sapphire window configured according to illustrative principles herein to better manage heat dissipation and/or to increase electronic circuitry density for added functionality. Example devices that may utilize a diamond coated sapphire window configured according to illustrative embodiments may include a mobile phone, a smartphone, a tablet computer, a watch crystal, a laptop computer, a consumer device, and the like.

The diamond coating may comprise a single or poly-crystalline diamond. Moreover, the coating may comprise a nano-crystalline diamond.

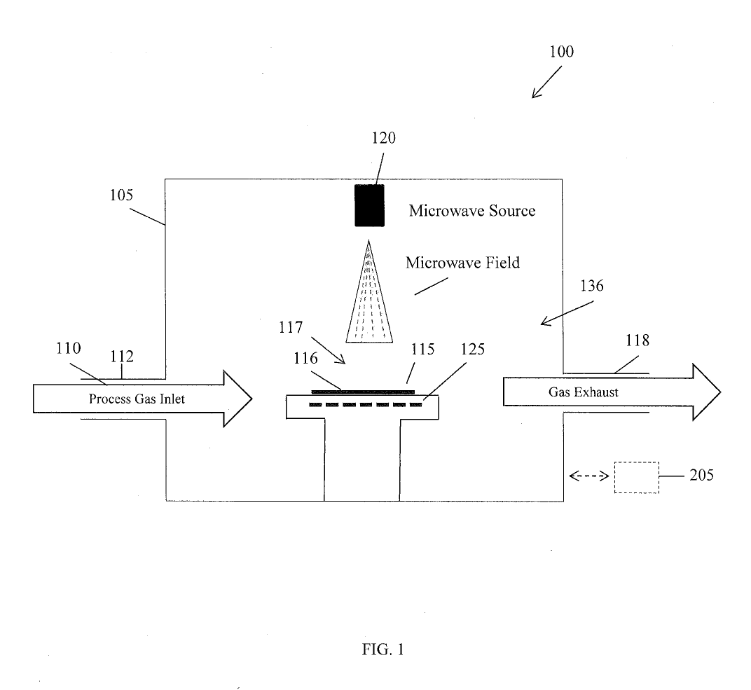

FIG. 1 shows an example of a system for coating a sapphire material, such as, e.g., a sapphire substrate, with a deposited carbon film, according to the principles of illustrative embodiments of the disclosure. As seen, the system 100, may include an evacuation chamber 105 configured to create a partial pressure of process gas 110, including molecular or atomic hydrogen, as well as one or more hydrocarbons, which may include, but are not limited to, methane. Additionally, the environmental gas process may also contain nitrogen, oxygen, inert gases such as argon, and other process gasses. A stage 125 supporting or holding target sapphire material 115 may itself be temperature controlled, i.e., cooled or heated. The gas 110 may flow from a source 112 and exit out an exhaust 118.

The system 100 in FIG. 1 may coat a layer of carbon film 116, i.e., a diamond film, on the target sapphire material 115 to provide a transparent, strong, scratch-resistant surface or window with passive cooling characteristics. In some applications, however, the resulting product may not be transparent, but rather translucent or even opaque. The resultant window may have applications for many consumer products including, e.g., touch screens in a mobile phone, tablet computer, a watch crystal and a laptop computer, where maintaining a strong, scratch-free surface is of primary importance. Moreover, the resulting product may be used in industrial type applications where optically transparent scratch-resistant windows may be required. The diamond film provides for a passive cooling property for both optic and, in the case of electronic displays, the actual device.

According to an embodiment of the disclosure, the target sapphire material 115 may be placed onto the stage 125 (which may be a type of holding device) within the evacuated chamber 105. As noted, the stage 125 may or may not be cooled. The stage 125 may be configured or adjustable to move in any one or more dimensions of 3-D space. Upon achieving an appropriate partial pressure 136, the gas 110 may be excited by a microwave source 120 in order to introduce plasma 117 within the system 100 (or 200). The gas composition is selected such that carbon film 116 or diamond film may be deposited onto the target sapphire material 115. While various allotropes of carbon may be deposited, the gas composition can be maintained in such a fashion as to preferentially etch non-diamond allotropes, leaving a final deposition that is primarily of the diamond allotrope of carbon. The thickness of the carbon film 116 (or diamond layer) created on the sapphire material 115 may be related to the specific application, and customizable from a few nanometers to many microns, such as may be needed by a particular application. For example, the thickness of the carbon film 116 (or diamond layer) may have a thickness selected from a range of about 1 nm to about 10 μm. However, greater (or lesser) thicknesses may be achieved as needed. In some embodiments, the thickness of the carbon film 116 (or diamond layer) may be any thickness selected from the range of about 2 nm to about 100 nm. Moreover, in some embodiments, the thickness of the carbon film 116 (or diamond layer) may be any thickness selected from the range of about 100 nm to about 5 mm. Moreover, in some embodiments, the thickness of the carbon film 116 (or diamond layer) may be greater than 10 μm. In some embodiments, the thickness of the sapphire material 115 (or substrate) may be about 100 μm to about 500 μm. However, the thickness of the sapphire material 115 may vary, and may be more than 500 μm. In some embodiments, the thickness of the sapphire material 115 may be less than 100 μm.

The orientation of the microwave source 120 relative to the target material 115 may vary. Also, the position of the microwave source 120 relative to the target material 115 may vary. Moreover, the power and/or frequencies of the microwave source 120 may vary. Moreover, one or more surfaces of the target material 115 may be targeted for carbon film deposition.

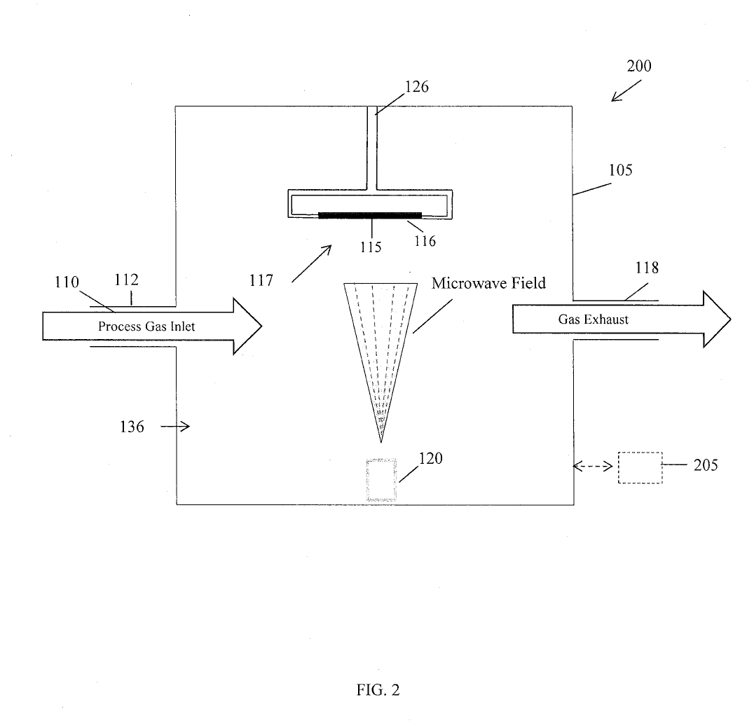

FIG. 2 shows an example of another system 200 for coating a material, such as, e.g., a sapphire substrate, with a deposited carbon film, according to the illustrative embodiments of the disclosure. The system 200 of FIG. 2 is similar to the system 100 of FIG. 1, but shows a different orientation of the microwave source 120 relative to the sapphire material 115. In this example, the microwave source 120 is oriented or located below the sapphire material 115. In other implementations, the relative orientation of the microwave source 120 relative to the sapphire material 115 may be any practical configuration. The microwave source 120 and the sapphire material 115 may be proximate one another. The power and/or frequency of the microwave source may vary during a particular coating process cycle, or may vary from one process cycle to another process cycle.

The sapphire material 115 may comprise multiple surfaces to have a carbon film/diamond created thereupon. A securing device 126 may be used to hold the sapphire material 115 in different positions relative to the microwave source 120. The securing device 115 may be adjustable in two or more different axes. The securing device 126 may be cooled or heated, as warranted, to improve deposition of the carbon film thereon. Moreover, a computer controller 205 may control the operations of the various components of the systems 100 and 200, and process of FIG. 3. For example, the controller 205 may control various parameters of the process, e.g., at least one of: the gas flow, the temperatures of the stage 125 and the securing device 126, the start and stop times of the microwave field, the intensity of the microwave field, targeting of the microwave field towards the substrate which may be selective targeting on a portion of the sapphire material 115, orientation of the sapphire material 115, the pressure(s) within the chamber 105, including possible evacuation of the chamber 105, thickness of the carbon film on the sapphire material 115, process duration, and the like.

FIG. 3 is a flow diagram of an example process, the steps of the process performed according to illustrative embodiments of the disclosure, starting at step 300. The process of FIG. 3 may include a type of chemical vapor deposition (CVD) and may employ, e.g., the devices of FIG. 1 or FIG. 2. The steps of this process may be in a different order than as shown. At optional step 301, a sapphire substrate, such as sapphire material 115, may be pre-treated. The pre-treatment may be accomplished in different ways. For example, the surface of the sapphire substrate may be pre-treated to facilitate the nucleation of carbon species on the sapphire substrate surface. This pre-treatment may include decoration of the surface with carbon particles. The surface may also be prepared by roughening or a texturing of the sapphire substrate surface. The texturing may be performed through an ionic etch process (among other ways). Additionally, or alternatively, the sapphire surface may be pre-treated by deposition with a thin film of less than 1 monolayer of metallic film. In some applications, the thickness of the metallic film may be from a few nanometers to several nanometers. For example, the thickness of the metallic film may be about 2 nm, about 3 nm, or about 4 nm. Moreover, in some applications, the thickness of the metallic film may be, for example, more than 4 nm or less than 2 nm. In some applications, the thickness of the metallic film may, for example, range from about 2 nm to about 10 nm.

At step 302, an environment such as, e.g., chamber 105 may be evacuated. At step 304, a holding device such as, e.g., stage 110 or securing device 126 may be provided. At step 305, a process gas may be provided. This may be provided in an environment such as, e.g., that shown in FIG. 1 or FIG. 2. The process gas may include one or more of a carbon-based gas, a hydrocarbon-based gas, methane, an inert gas, oxygen and nitrogen. This step may include creating a partial pressure of the process gas in an environment such as chamber 105. The environment may be evacuated prior to providing the process gas. The process gas may be flowed as necessary into the environment, such as the chamber 105, to provide a continual source of carbon for as long as required by a particular iteration of the process.

At step 310, microwave source 120, may be provided. This may include providing a microwave generator within or proximate a gas chamber such as, e.g., chamber 105. At step 315, a sapphire substrate, such as, e.g., target sapphire material 115, may be provided. The target sapphire material 115 may be held by a holding device such as, e.g., securing device 126 or stage 125.

At step 320, the microwave source, such as, e.g., microwave source 120, may provide a microwave field directed towards the substrate and/or process gas. At step 325, plasma may be created by the microwave field. At step 330, a carbon film may be deposited on the sapphire substrate. The deposited carbon film may include a diamond film. The diamond film may comprise a coating of a single or poly-crystalline diamond. Moreover, the film may comprise a nano-crystalline diamond. The carbon film may be deposited on one or more surfaces of the sapphire substrate, including top surface, bottom surface, one or more side surfaces, or any combination of surfaces, including partial or full surface areas of any one or more of the surfaces.

At step 335, the holding device may be controlled such as by controller 205. The holding device such as, e.g., securing device 115 or stage 125, may be repositioned to reorient the substrate in relation to the microwave source. This may reorient the sapphire substrate in one or more of three dimensions. The holding device may also be controlled to raise or lower its temperature and, therefore, also raise or lower the temperature of the target sapphire substrate 115.

At step 340, the process gas may be controlled such as starting the flow, stopping the flow, increasing or decreasing the rate of process gas flow, and/or changing the mix of gas compositions of the process gas. This may be accomplished by, e.g., controller 205.

At step 345 the microwave source such as, e.g., microwave source 120 may be controlled. The control may include starting and stopping the generation of a microwave field, setting or changing intensity of the microwave field, targeting of the microwave field and/or repositioning of the microwave field in relation to the substrate. Controlling or varying the microwave field, and hence the resulting plasma 117, may provide control of the thickness of the carbon film deposited on the substrate and/or the rate of deposition. The process may end at step 350.

The resulting matrix produced by the process of FIG. 3 may comprise a target sapphire substrate 115 having an applied carbon film with an efficient heat sink capability. The matrix may be substantially transparent. The applied carbon film may be a diamond film. The applied carbon film may comprise a diamond film that is formed with and/or at the surface of the substrate. The diamond film on the sapphire material may provide improved thermal conductivity or improved heat dissipation properties for a device employing a resulting window made by the process of FIG. 3. This may permit devices to better manage heat dissipation and/or to increase electronic circuitry density for added functionality. The sapphire material with diamond film may be per-constructed (or net-shaped) to be sized and shaped for implementation in an intended device.

In illustrative embodiments, the process duration for depositing the carbon film in the process of FIG. 3 may be several minutes to several hours. The resulting carbon film coated sapphire material may be subsequently finished or shaped, as needed, if at all, to produce a window. The carbon film coated material may be used in, e.g., a window in optics or an electronic device for cooling the electronic device. In illustrative embodiments, the resulting window may have a thermal conductivity greater than 26 W m⁻¹ K⁻¹ at 300K through the face (out-of-plane) of the window. However, the in-plane thermal conductivity may be much higher, such as greater than 1000 W m⁻¹ K⁻¹ at 300K along the surface of the window. This high relative in-plane conductivity may be maintained by controlling two properties. The first property is the density of the diamond film, which, in illustrative embodiments, may be maintained at a value of 3000 kg/m³ by optimizing the deposition parameters, particularly chamber pressure and substrate temperature. The second property is the ratio of carbon allotropes in the film; i.e., chamber gas chemistry (e.g., the percentage of hydrogen present in the chamber atmosphere) and microwave power, which may be controlled so as to allow creation of a film demonstrating a ratio of diamond allotropes (sp³ bonded carbon) to non-diamond allotropes (sp² bonded carbon) greater than 9.0.

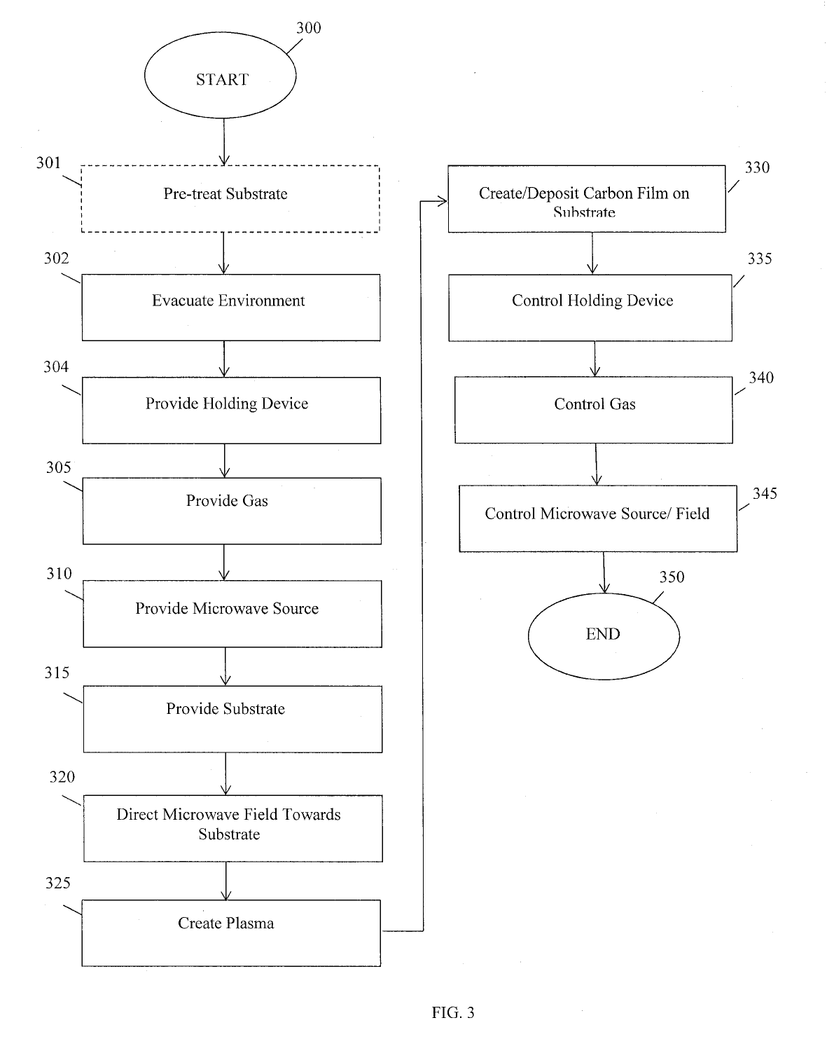

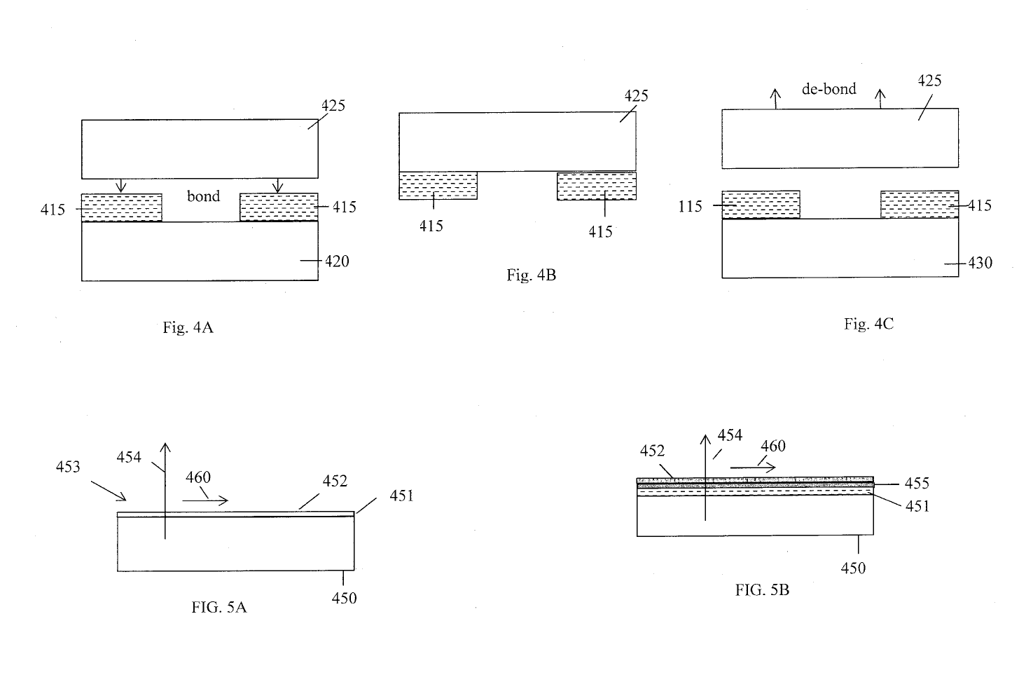

FIGS. 4A-4C show an example of a simplified process of transfer bonding, according to illustrative embodiments of the disclosure. In FIG. 4A, pattern of diamond 415 may be created on the surface of a source substrate 420, such as by the process of FIG. 3. The source substrate 420 may be formed from any of a variety of materials, such as silicon or metal (e.g., preferably a lower cost metal). A transfer carrier 425 may be employed to pick the diamond layer 415 from the source substrate 420, as shown in FIG. 4B, and moved to a destination substrate 430, which may be a destination sapphire substrate such as, e.g., sapphire material 115. In some transfer techniques, the adhesion of the diamond layer 415 to each subsequent carrier preferably is stronger than the previous surface. The diamond layer 415 may bond to the destination substrate 430. Alternatively, a dissolvable transfer carrier 425 may be employed, which is dissolved after transferring the diamond layer 415 to the destination substrate 430. Other transfer techniques may also be employed. The pattern of the diamond layer 415 may be any pattern including a pattern that covers an entire surface or partial surface of a sapphire window, i.e., an entire or partial surface (or more than one surface) of, e.g., sapphire material 115. The diamond layer 415 may be transferred to any surface of the destination substrate 430, including a top surface, a bottom surface, one or more side surfaces, or any combination of surfaces, including partial or full surface areas of any one or more of the surfaces. The destination substrate 430 may be pre-constructed (or net-shaped) to be sized and shaped for implementation in an intended device. The diamond layer 415 on the destination substrate 430 may comprise an efficient heat sink, when employed in a device requiring heat dissipation. For example, the heat sink may conductively remove heat from an underlying device.

As noted above with regard to FIGS. 1 and 2, the processes of producing a diamond heat sink as describe herein may be controlled by a computer (e.g., computer 205) that may control the creation of the diamond layers 415. The computer may control the pattern and location of the diamond layer 415. The computer may control the sequencing, and may control the transfer bonding, the CVD process, and/or similar process.

The pattern of diamond 415 may comprise a coating or layer of a single or poly-crystalline diamond. Moreover, the pattern of diamond 415 may comprise a nano-crystalline diamond.

FIG. 5A is an example of a device utilizing a sapphire substrate having a diamond layer, configured according to various embodiments of the disclosure. Device 450 may be configured with a sapphire window 451 with a diamond layer 452 coating at least one surface of the sapphire window 451. The diamond layer may be in the form of a film bonded to the sapphire window 451.

The sapphire window 451 with diamond layer 452 may be constructed such as, e.g., described above in relation to the processes of FIGS. 3-4C. The device 450 may comprise, but is not limited to, e.g., a mobile phone, a smartphone, a tablet computer, a watch crystal, an optical device, a laptop computer, or the like. The combination of diamond layer 452 and sapphire window 451 may provide a strong, scratch-free surface while also providing an improved heat sink function for the device 450. The device 450 may generate heat typically due to electronics associated with (or within) the device 450. The sapphire window 451 and diamond layer 452 may provide significantly enhanced thermal dissipation properties so that the operational functions of the device 450 may be improved such as by permitting additional circuitry to be included or higher density electronics used. Moreover, the sapphire window 451 and diamond layer 452 may assist in extending the useable life of the device 450 by improving heat dissipation characteristics for the device 450. The diamond layer 452 or coating may comprise a single or poly-crystalline diamond. Moreover, in some embodiments, the diamond layer 452 may comprise a nano-crystalline diamond. In some embodiments, the thickness of the sapphire window 451 (or substrate) may be about 100 μm to about 500 μm. However, in some embodiments, the thickness of the sapphire window 451 may vary, and may be more than 500 μm. In some embodiments, the thickness of the sapphire window 451 may be less than 100 μm.

In some applications, the thickness of the diamond layer 452 created on the sapphire window 451 may be related to the specific application. The diamond layer 452 may be a film/coating. The diamond layer 452 may be customizable from a few nanometers to many microns, such as may be needed by a particular application. For example, the thickness of the diamond layer 452 may be selected from a range of about 1 nm to about 10 μm. However, greater (or lesser) diamond layer thicknesses may be achieved as needed. In some embodiments, the thickness of the diamond layer 452 may be any thickness selected from the range of about 2 nm to about 100 nm. Moreover, in some embodiments, the thickness of the diamond layer 452 may be any thickness selected from the range of about 100 nm to about 5 mm. Moreover, in some embodiments, the thickness of the diamond layer 452 may be greater than 10 μm. Various embodiments may vary the thickness of a single diamond layer 452.

The resulting window (i.e., the sapphire window 451 with diamond layer 452) of FIG. 5A may have a thermal conductivity as discussed in relation to FIG. 3 above. That is, the resulting window may have a thermal conductivity greater than 26 W m⁻¹ K⁻¹ at 300K through the face (out-of-plane 452) of the resulting window. However, the in-plane (denoted by arrow 460) thermal conductivity is greater than 1000 W m⁻¹ K⁻¹ at 300K along the surface 453 of the resulting window. In some applications, the heat sink may be employed in optical applications. The heat sink may be resistant to scratching, mechanical wear, and chemical corrosion.

FIG. 5B is an example of a device using a pre-treated sapphire window configured in accordance with illustrative embodiments. The device is similar to the device of FIG. 5A, except that it may include a pre-treatment 454 of the sapphire window 451. The pre-treatment 454 of the surface of the sapphire window 451 may be pre-treated to facilitate the nucleation of carbon species on the sapphire surface. The pre-treatment may be accomplished, for example, as described in step 301 of FIG. 3. Among other things, the pre-treatment 454 may include a deposition of less than 1 monolayer of a metallic film. The metallic film may be configured between a surface of the sapphire window 451 and the diamond layer 452.

While the disclosure has been described in terms of exemplary embodiments, those skilled in the art will recognize that the disclosure can be practiced with modifications in the spirit and scope of the appended claims. These examples are merely illustrative and are not meant to be an exhaustive list of all possible designs, embodiments, applications or modifications of the disclosure.

What is claimed:

1. A window for use in a device, the window comprising:
a sapphire material; and
a diamond film layer on the sapphire material.

2. The window of claim 1, wherein the device comprises one of: a smartphone, a tablet computer, a watch crystal, a laptop computer and a consumer device.

3. The window of claim 1, wherein the diamond film layer comprises a single-crystal or poly-crystalline diamond.

4. The window of claim 1, wherein the diamond film layer comprises a nano-crystalline diamond.

5. The window of claim 1, wherein the sapphire material is configured having a thickness of about 100 μm to about 500 μm.

6. The window of claim 1, wherein the sapphire material is configured having a thickness greater than 500 μm.

7. The window of claim 1, wherein the sapphire material is configured having a thickness less than 100 μm.

8. The window of claim 1, wherein the diamond film layer may have a thickness selected from a range of about 1 nm to about 10 μm.

9. The window of claim 1, wherein the diamond film layer may have a thickness selected from the range of about 2 nm to about 100 nm.

10. The window of claim 1, wherein the diamond film layer may have a thickness of about 100 nm to about 5 mm.

11. The window of claim 1, wherein the diamond film layer acts as a heat sink in conducting heat from the device.

12. The window of claim 1, wherein the window has a thermal conductivity greater than 26 W m⁻¹ K⁻¹ at 300K through a face of the window.

13. The window of claim 1, wherein the window has an in-plane thermal conductivity greater than 1000 W m⁻¹ K⁻¹ at 300K along a surface of the window.

14. A device comprising:
a sapphire window; and
a diamond layer coating the sapphire window configured with enhanced thermal dissipation properties to dissipate heat generated by the device.

15. The device of claim 14 wherein the device comprises one of: a smartphone, a tablet computer, a watch crystal, a laptop computer and a consumer device.

16. The device of claim 14, wherein the diamond layer comprises a single or poly-crystalline diamond.

17. The device of claim 14, wherein the diamond layer comprises a nano-crystalline diamond.

18. The device of claim 14, wherein the sapphire window is configured with a thickness of about 100 μm to about 500 μm.

19. The device of claim 14, wherein the sapphire window is configured with a thickness greater than 500 μm.

20. The device of claim 14, wherein the sapphire window is configured with a thickness less than 100 μm.

21. The device of claim 14, wherein the diamond layer has a thickness selected from a range of about 1 nm to about 10 μm.

22. The device of claim 14, wherein the diamond film layer has a thickness selected from the range of about 2 nm to about 100 nm.

23. The device of claim 14, wherein the diamond layer has a thickness of about 100 nm to about 5 mm.

24. The device of claim 14, wherein the diamond layer comprises a film.

25. A window for use in a device having at least one heat generating component, the window comprising:
a sapphire material; and
a carbon-based transparent heat sink in contact with the sapphire material, the carbon-based transparent heat sink configured to be in thermally conductive contact with the at least one heat generating component.

26. The window of claim 25 wherein the heat sink comprises diamond on the sapphire material.

27. The window of claim 25 wherein the heat sink comprises a chemically vapor deposited film on the sapphire material.

28. The window of claim 25 wherein both the sapphire material and transparent heat sink form a combined heat sink.
